(19) United States
(12) Patent Application Publication
(10) Pub. No.: US 2022/0224342 A1
(43) Pub. Date: Jul. 14, 2022

(54) CLOCKING ARCHITECTURE FOR A MULTI-DIE PACKAGE

(71) Applicants: Atul Maheshwari, Portland, OR (US); Ankireddy Nalamalpu, Portland, OR (US); Mahesh K. Kumashikar, Bangalore (IN); Lai Guan Tang, Tanjung Bungah (MY)

(72) Inventors: Atul Maheshwari, Portland, OR (US); Ankireddy Nalamalpu, Portland, OR (US); Mahesh K. Kumashikar, Bangalore (IN); Lai Guan Tang, Tanjung Bungah (MY)

(21) Appl. No.: 17/711,784

(22) Filed: Apr. 1, 2022

(51) Int. Cl. H03L 7/07; H03L 7/08

(52) U.S. Cl. CPC H03L 7/07; H03L 7/08

(57) ABSTRACT

A device including a system phase lock loop circuit to: receive a primary reference clock, generate a reference clock from the primary reference clock, and transmit the reference clock; and a phase lock loop circuit to receive the reference clocks, generate a sub-reference clock from the received respective reference clocks, and transmit the sub-reference clock from the phase lock loop circuit to drive operation of a first chiplet using the respective sub-reference clock, wherein the sub-reference clock drives the first chiplet.

### BACKGROUND

The present disclosure relates generally to integrated circuit devices, such as multi-die packages utilizing one or more chiplets. More particularly, the present disclosure relates to a clocking architecture within multi-die packages.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light and not as admissions of prior art.

Integrated circuits may be utilized to perform various functions. Moreover, to perform faster and more complex functions, multiple integrated circuit die and/or chiplets may be used together in a multi-die package. In some cases, it may be advantageous to provide a local clock signal to one or more die or chiplets in a multi-die package. To accomplish this, a number of phase lock loop (“PLL”) circuits may be communicatively connected to the die and/or chiplets in a multi-die package. The PLL circuits may receive a primary reference clock and generate a sub-reference clock for the chiplets based on the primary reference clock. The sub-reference clocks may be multiples of the primary reference clock and may be phase-locked to the primary reference clock.

However, in a multi-die package with a synchronous system, skew may be introduced between the clocks of the various chiplets based on their separate PLL operations. This skew may be a significant source of latency and performance degradation. Specifically, this skew may be problematic when crossing clock domains from one chiplet to another.

### BRIEF DESCRIPTION OF THE DRAWINGS

Various aspects of this disclosure may be better understood upon reading the following detailed description and upon reference to the drawings in which:

FIG. 1 is a block diagram of an integrated circuit device with several phase lock loop circuits and chiplets, in accordance with an embodiment of the present disclosure;

FIG. 2 is a block diagram of an integrated circuit device with a system phase lock loop circuit, in accordance with an embodiment of the present disclosure;

FIG. 3 is a block diagram of an integrated circuit device with several phase lock loop circuits, in accordance with an embodiment of the present disclosure;

FIG. 4 is a block diagram of an integrated circuit device with two system phase lock loop circuits, in accordance with an embodiment of the present disclosure;

FIG. 5 is a block diagram of a data processing system including an integrated circuit device, in accordance with an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present disclosure describes systems and techniques related to clocking architecture in a multi-die package to provide accurate clock signals to chiplets within the multi-die package. To achieve this, chiplets may be communicatively connected to PLL circuits, which may provide a sub-reference clock based on a primary reference clock, as will be discussed in greater detail herein. To reduce skew, a system PLL circuit may receive the primary reference clock signal and provide reference clocks, derived from the primary reference clock, to the PLL circuits within the multi-die package for the chiplets to receive. The PLL circuits may provide sub-reference clocks to the chiplets, derived from the reference clock. The chiplets may use the sub-reference clocks to perform chiplet operations in the synchronous multi-die package.

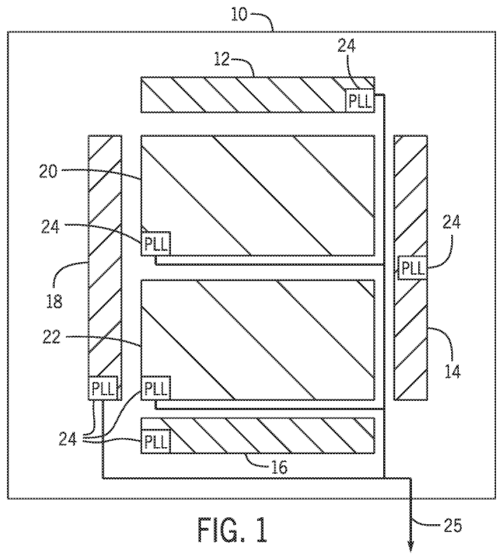

With the foregoing in mind, FIG. 1 illustrates a block diagram of an integrated circuit device 10 that may include multiple chiplets and/or die, for example chiplets 12, 14, 16, 18, 20, and 22 (chiplets 12-22). In some embodiments, the integrated circuit device 10 may be a multi-die package, such that each chiplet 12-22 may perform shared or unique functions of the multi-die package. For example, in some embodiments, the chiplets 12-22 may all have different functions. However, in some embodiments, at least some of the chiplets 12-22 may perform similar functions as each other.

In some embodiments, the chiplets 12-22 may include respective PLL circuits 24. In the illustrated embodiment shown in FIG. 1, each of the chiplets 12-22 may include one of the PLL circuits 24. However, as will be described in greater detail below, in some embodiments, the PLL circuits 24 in the integrated circuit device 10 may not have a proportion to the chiplets 12-22 of 1:1. For example, one of the PLL circuits 24 may be connected to two, three, four, or any other number of the chiplets 12-22 driving at least one of the chiplets 12-22 from off the chiplet being driven. Further, in some embodiments, at least some of the PLL circuits 24 may independent and not included in the chiplets 12-22 themselves. Alternatively, in some embodiments, at least some of the PLL circuits 24 may be implemented as a portion of soft logic implemented in a programmable fabric (e.g., a field-programmable gate array) of one of the chiplets 12-22.

The PLL circuits 24 may receive a primary reference clock and send corresponding sub-reference clocks to the respective chiplets 12-22 to help coordination the timing of functions of the chiplets 12-22 in a multi-die package. Accordingly, in some embodiments, some of the chiplets 12-22 may share a common sub-reference clock. To accomplish this, each of the PLL circuits 24 may receive a primary reference clock 25 from a same source. The source may be any appropriate reference clock source that may be internal or external to the integrated circuit device 10. The PLL circuits 24 may then generate and send sub-reference clocks to the chiplets 12-22 based on the primary reference clock 25. However, there may be inefficiencies associated with each of the PLL circuits 24 receiving a primary reference clock 25 from the same reference clock source. For example, the PLL circuits 24 may have little control over the exact timing of the arrival of the primary reference clock 25. Further, each of the PLL circuits 24 may independently manage respective sub-reference clocks and may not generate identical sub-reference clocks for the chiplets 12-22 generating clock skew between the sub-reference clocks. Additionally, skew may increase when crossing clock domains. In some embodiments, these factors and others may contribute to the overall skew in the system potentially negatively impacting latency and performance of the integrated circuit device 10.

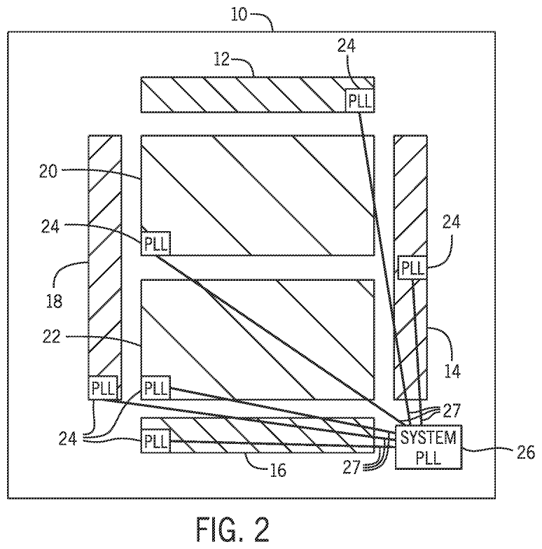

Keeping this in mind, FIG. 2 illustrates an example embodiment of the integrated circuit device 10 including a system PLL circuit 26. The system PLL circuit 26 may substitute as a reference clock source and may generate reference clocks for the PLL circuits 24 to use and communicate to the chiplets 12-22. In some embodiments, the system PLL circuit 26 may occupy an entire chiplet dedicated for the system PLL circuit 26. Further, in some embodiments, the system PLL circuit 26 may be a part of one of the chiplets 12-22. For example, in some embodiments, a portion of soft logic of one of the chiplets 12-22 may be programmed to operate as the system PLL circuit 26. Indeed, in some embodiments, one of the PLL circuits 24 may be configured to operate as the system PLL circuit 26.

To substitute as a reference clock source, the system PLL circuit 26 may receive a primary reference clock 25 from a reference clock source that may be the reference clock source referred to in FIG. 1. In some embodiments, the system PLL circuit 26 may be the only component in the integrated circuit device 10 to receive the primary reference clock 25 from the reference clock source. For example, rather than receive the primary reference clock 25 from the reference clock source, the PLL circuits 24 may instead receive reference clocks 27 generated by the system PLL circuit 26. Indeed, in some embodiments, the system PLL circuit 26 may, in response to receiving the primary reference clock 25 from the reference clock source, generate a number of reference clocks 27. The reference clocks 27 may be identical to the primary reference clock 25 or otherwise based on the primary reference clock 25. The system PLL circuit 26 may supply the reference clocks 27 to the PLL circuits 24 in the integrated circuit device 10 through routing circuitry. In some embodiments, the reference clocks 27 received by the PLL circuits 24 may be identical or nearly identical to each other. Alternatively, the reference clocks 27 may be adjusted to reduce skew by driving the reference clocks 27 differently to account for various delays, such as propagation delays and process corners.

By utilizing the system PLL circuit 26 to provide reference clocks 27 to the PLL circuits 24 based on the primary reference clock 25 from the reference clock source, several benefits may be realized. For instance, the skew in the system may be reduced, as there may be fewer differences in the routing circuitry sending the reference clocks 27 to the PLL circuits 24 as compared to the methods of receiving the primary reference clock 25 from the reference clock source, which may be external to the integrated circuit device 10. Therefore, cascading the reference clocks 27 from the system PLL circuit 26 to the PLL circuits 24 may ensure that the PLL circuits 24 remain synchronized. This skew reduction may ensure that the chiplets 12-22 are able to operate their respective functions synchronously or otherwise based on an accurate (i.e., consistent throughout the chiplets 12-22) sub-reference clock.

Further, the board design of the integrated circuit device 10 may be simplified through the inclusion of the system PLL circuit 26. For example, there may be fewer primary reference clocks 25 being received by members of the integrated circuit device 10. For example, only the system PLL circuit 26 may receive a primary reference clock 25 from the reference clock source. This may further be a benefit to users of the integrated circuit device 10. For example, a user, which may use software such as a version of Quartus by Altera™, may only need to connect the system PLL circuit 26 to the reference clock source. In turn, the system PLL circuit 26 may then handle remaining clock architecture needs by supplying the reference clocks 27 derived from the primary reference clock 25 to the PLL circuits 24. Further, as may be appreciated, the single connection (e.g., trace) to the system PLL circuit 26 may result in improved in design simplicity, area costs, and/or material costs for the integrated circuit device 10, due to at least the reasons mentioned.

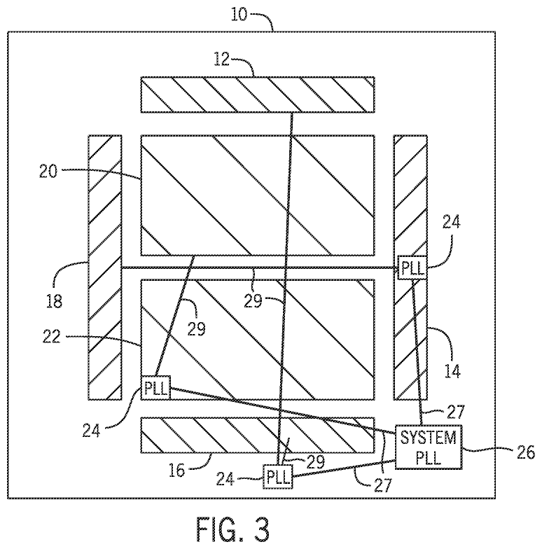

Keeping the foregoing in mind, FIG. 3 illustrates an example embodiment with different placements and operations of the PLL circuits 24 within the integrated circuit device 10 than used in the embodiment of FIG. 2. The embodiment in FIG. 3 functions similar to the embodiment of FIG. 2 described above except that the PLL circuits 24 may provide a respective sub-reference clock 29 to more than one of the chiplets 12-22. For example, in an embodiment where the chiplets 12 and 16 operate similar functions or utilize similar clocks, one of the PLL circuits 24 may provide a sub-reference clock 29 to both chiplets 12 and 16. Furthermore, the PLL circuit 24 may be integrated into the chiplet 12 or 16 and may provide the sub-reference clock 29 to the other chiplet 12 or 16. In another embodiment, the PLL circuit 24 may be separate from both the chiplet 12 and the chiplet 16 and may provide the sub-reference clock 29 to the chiplets 12 and 16. Further, similar connectivity between the chiplets 12-22 and the PLL circuits 24 may be established for any number of the chiplets 12-22 that perform similar functions or otherwise may benefit from the sharing of a sub-reference clock 29 from one of the PLL circuits 24. Furthermore, although each of the PLL circuits 24 in FIG. 3 are shown to provide sub-reference clocks 29 to two chiplets, some embodiments may include the PLL circuits 24 driving different numbers of chiplets. For example, the PLL circuit 24 of a first chiplet (e.g., the chiplet 22) may provide a sub-reference clock 29 to the chiplet. In the same package, the PLL circuit 24 of a second chiplet (e.g., the chiplet 14) may provide respective sub-reference clocks 29 to 2, 3, 4, or more chiplets. By driving more than one chiplet using a respective instantiation of the PLL circuit 24, the number of PLL circuits 24 in the integrated circuit device 10 may be reduced by the sharing of sub-reference clocks 29 between at least some of the chiplets 12-22. Furthermore, in some embodiments, this may result in an improved efficiency in the integrated circuit device 10.

Further, in some embodiments, the PLL circuits 24 may be disposed external to the chiplets 12-22. For example, in some embodiments, the PLL circuits 24 may be disposed on an interconnect bridge that connects several of the chiplets 12-22 together, such as an EMIB. In some embodiments, having one or more of the PLL circuits 24 on an interconnect bridge may enable the connectivity required to transmit the sub-reference clock 29 from one of the PLL circuits 24 to two or more of the chiplets 12-22. Additionally or alternatively, the PLL circuits 24 may be located anywhere on the integrated circuit device 10.

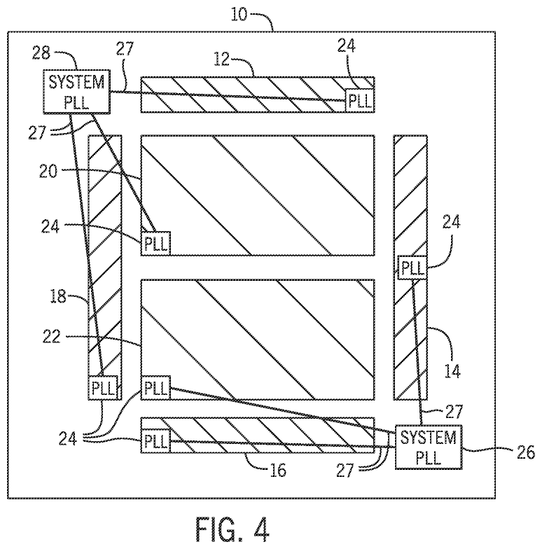

In some embodiments, multiple instantiations of the system PLL circuit 26 may be implemented in the multi-die package. For instance, multiple instantiations may be implemented for routing design, power management, simplicity of design, interference/line coupling reductions, or any other reason that may benefit from multiple instantiations. Keeping the foregoing in mind, FIG. 4 illustrates an example embodiment where a system PLL circuit 28 is included along with the system PLL circuit 26 in the integrated circuit device 10. In some embodiments, the system PLL circuits 26 and 28 may route the sub-reference clocks 29 to different PLL circuits 24. For example, in some embodiments, any group of the PLL circuits 24 may utilize or otherwise benefit from a reduction in radio-frequency interference (RFI) in the signals delivering the reference clocks to the PLL circuits 24. In some embodiments, the addition of the system PLL circuit 28 may be specified by a standard of the first group of the PLL circuits 24. Further, in some embodiments, some of the chiplets 12-22 may utilize or otherwise benefit from a reduction in radio-frequency interference (RFI) in the signals delivering the sub-reference clocks 29 to chiplets 12-22. In some embodiments, the addition of the system PLL circuit 28 may be specified by a standard of some of the chiplets 12-22. Furthermore, the system PLL circuit 26 and/or the system PLL circuit 28 may dither the clocks being sent to the PLL circuits 24. For example, the system PLL circuit 26 and/or the system PLL circuit 28 may apply a low-level noise or other appropriate amounts of noise to the communications to mask RFI on the communications. Further, in some embodiments, at least one group of the PLL circuits 24 may not utilize such dithering. Accordingly, in some embodiments, the second system PLL circuit 28 may transmit the reference clock 27 to the second group of the PLL circuits 24 without dithering the communications containing the reference clock 27. Further, although separate system PLL circuits 26 and 28 are disclosed as communicating to the two groups of PLL circuits 24, in some embodiments, the system PLL circuit 26 may selectively dither communications to the PLL circuits 24 that utilize such dithering.

Further, in some embodiments, there may be periods of time where one or more of the chiplets 12-22 are inactive. Accordingly, the system PLL circuits 26 and 28 may power gate one or more of the chiplets 12-22 by stopping transmission of the reference clocks 27 to the PLL circuits 24. To accomplish this, in some embodiments, the PLL circuits 24, the system PLL circuit 26, the system PLL circuit 28, and/or the chiplets 12-22 may have address identifiers that may be used to select which communication is to be disabled. In some embodiments, one or more of the chiplets 12-22 may indicate via a flagged signal or other means that the sub-reference clock 29 is not needed. In some embodiments, clock propagation may be disabled until the chiplets 12-22 are to be utilized. In some embodiments, all chiplets 12-22 coupled to a respective system PLL circuit 26 or 28 may be toggled between active and inactive states at once. In some embodiments, this clock gating may result in power savings within the integrated circuit device 10.

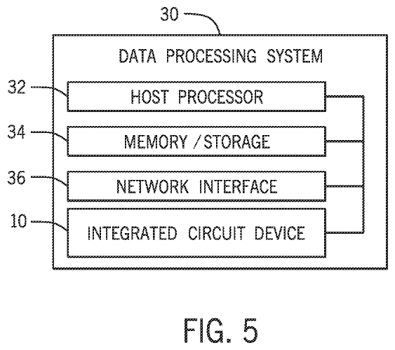

Keeping the foregoing in mind, the integrated circuit device 10 may be a part of a data processing system or may be a component of a data processing system that may benefit from use of the techniques discussed herein. For example, the integrated circuit device 10 may be a component of a data processing system 30, shown in FIG. 5. The data processing system 30 includes a host processor 32, memory and/or storage circuitry 34, and a network interface 36. The data processing system 30 may include more or fewer components (e.g., electronic display, user interface structures, application specific integrated circuits (ASICs)).

The host processor 32 may include any suitable processor, such as an INTEL® XEON® processor or a reduced-instruction processor (e.g., a reduced instruction set computer (RISC), an Advanced RISC Machine (ARM) processor) that may manage a data processing request for the data processing system 30 (e.g., to perform machine learning, video processing, voice recognition, image recognition, data compression, database search ranking, bioinformatics, network security pattern identification, spatial navigation, or the like). The memory and/or storage circuitry 34 may include random access memory (RAM), read-only memory (ROM), one or more hard drives, flash memory, or the like. The memory and/or storage circuitry 34 may be considered external memory to the integrated circuit device 10 and may hold data to be processed by the data processing system 30 and/or may be internal to the integrated circuit device 10. In some cases, the memory and/or storage circuitry 34 may also store configuration programs (e.g., bitstream) for programming a programmable fabric of the integrated circuit device 10. The network interface 36 may permit the data processing system 30 to communicate with other electronic devices. The data processing system 30 may include several different packages or may be contained within a single package on a single package substrate.

In one example, the data processing system 30 may be part of a data center that processes a variety of different requests. For instance, the data processing system 30 may receive a data processing request via the network interface 36 to perform machine learning, video processing, voice recognition, image recognition, data compression, database search ranking, bioinformatics, network security pattern identification, spatial navigation, or some other specialized task. The host processor 32 may cause a programmable logic fabric of the integrated circuit device 10 to be programmed with a particular accelerator related to a requested task. For instance, the host processor 32 may instruct that configuration data (bitstream) be stored on the memory and/or storage circuitry 34 or cached in sector-aligned memory of the integrated circuit device 10 to be programmed into the programmable logic fabric of the integrated circuit device 10. The configuration data (bitstream) may represent a circuit design for a particular accelerator function relevant to the requested task.

The processes and devices of this disclosure may be incorporated into any suitable circuit. For example, the processes and devices may be incorporated into numerous types of devices such as microprocessors or other integrated circuits. Exemplary integrated circuits include programmable array logic (PAL), programmable logic arrays (PLAs), field programmable logic arrays (FPLAs), electrically programmable logic devices (EPLDs), electrically erasable programmable logic devices (EEPLDs), logic cell arrays (LCAs), field programmable gate arrays (FPGAs), application specific standard products (ASSPs), application specific integrated circuits (ASICs), and microprocessors, just to name a few.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A device comprising: system phase lock loop (PLL) circuitry to: receive a primary reference clock, generate one or more reference clocks from the primary reference clock, and transmit the one or more reference clocks; and a plurality of PLL circuitries to: receive respective reference clocks of the one or more reference clocks, generate respective sub-reference clocks from the received respective reference clocks, and transmit the respective sub-reference clocks from respective PLL circuitries of the plurality of PLL circuitries to drive operations of a plurality of chiplets using the respective sub-reference clocks, wherein one or more of the respective sub-reference clocks drive one or more chiplets of the plurality of chiplets.

EXAMPLE EMBODIMENT 2. The device of example embodiment 1 comprising the plurality of chiplets, wherein each chiplet of the plurality of chiplets comprises a PLL circuitry of the plurality of PLL circuitries.

EXAMPLE EMBODIMENT 3. The device of example embodiment 2, wherein one of the plurality of chiplets comprises the system PLL circuitry.

EXAMPLE EMBODIMENT 4. The device of example embodiment 2, comprising a system PLL chiplet that comprises the system PLL circuitry.

EXAMPLE EMBODIMENT 5. The device of example embodiment 1 comprising the plurality of chiplets, wherein a chiplet of the plurality of chiplets comprises a corresponding PLL circuitry of the plurality of PLL circuitries and drives at least two chiplets of the plurality of chiplets.

EXAMPLE EMBODIMENT 6. The device of example embodiment 5, wherein the at least two chiplets are similar chiplets.

EXAMPLE EMBODIMENT 7. The device of example embodiment 6, wherein the at least two chiplets have a same function type.

EXAMPLE EMBODIMENT 8. The device of example embodiment 1, wherein the system PLL circuitry is to disable transmission of at least one of at least one of the one or more reference clocks to place a corresponding at least one of the chiplets in an idle mode.

EXAMPLE EMBODIMENT 9. A multi-die package comprising: first system phase lock loop (PLL) circuitry to: receive a primary reference clock, generate a first one or more reference clocks from the primary reference clock, and transmit the first one or more reference clocks; second system PLL circuitry to: receive the primary reference clock, generate a second one or more reference clocks from the primary reference clock, dither the second one or more reference clocks, and transmit the second one or more reference clocks; and a plurality of PLL circuitries comprising: a first group of PLL circuitries of the plurality of PLL circuitries to receive the first one or more reference clocks; and a second group of PLL circuitries of the plurality of PLL circuitries to receive the second one or more reference clocks.

EXAMPLE EMBODIMENT 10. The multi-die package of example embodiment 9, wherein the first group of PLL circuitries generates respective sub-reference clocks from the first one or more reference clocks and transmits the respective sub-reference clocks to drive operations of a plurality of chiplets.

EXAMPLE EMBODIMENT 11. The multi-die package of example embodiment 10, wherein the first system PLL circuitry disables transmission of at least one of the first one or more reference clocks to place a at least one of the chiplets in an idle mode.

EXAMPLE EMBODIMENT 12. The multi-die package of example embodiment 9, wherein the second group of PLL circuitries generates respective sub-reference clocks from the first one or more reference clocks and transmits the respective sub-reference clocks to drive operations of a plurality of chiplets.

EXAMPLE EMBODIMENT 13. The multi-die package of example embodiment 9, comprising a plurality of dedicated PLL chiplets that comprises the plurality of PLL circuitries.

EXAMPLE EMBODIMENT 14. The multi-die package of example embodiment 9, comprising a plurality of chiplets driven using the first and second one or more reference clocks, wherein the plurality of chiplets comprises the plurality of PLL circuitries.

EXAMPLE EMBODIMENT 15. The multi-die package of example embodiment 9, comprising: a plurality of chiplets driven using the first and second one or more reference clocks, and an interconnect that connects at least two of the plurality of chiplets, wherein at least one of the plurality of PLL circuitries is located on the interconnect.

EXAMPLE EMBODIMENT 16. A multi-die package comprising: first system phase lock loop (PLL) circuitry to: receive a primary reference clock, generate first reference clocks from the primary reference clock, and transmit the first reference clocks; and a first plurality of PLL circuitries to: receive the first reference clocks, generate first sub-reference clocks from the first reference clocks, and transmit the first sub-reference clocks from the first plurality of PLL circuitries to drive operation of a first plurality of chiplets; second system phase lock loop (PLL) circuitry to: receive the primary reference clock, generate a second reference clocks from the primary reference clock, and transmit the second reference clocks; and a second plurality of PLL circuitries to: receive the second reference clocks, generate second sub-reference clocks from the second reference clocks, and transmit the second sub-reference clocks from the second plurality of PLL circuitries to drive operation of a second plurality of chiplets.

EXAMPLE EMBODIMENT 17. The multi-die package of example embodiment 16, comprising the first plurality of chiplets, wherein the first plurality of PLL circuitries are not disposed on the first plurality of chiplets.

EXAMPLE EMBODIMENT 18. The multi-die package of example embodiment 16, comprising the first plurality of chiplets, wherein the first plurality of PLL circuitries are disposed on the first plurality of chiplets.

EXAMPLE EMBODIMENT 19. The multi-die package of example embodiment 16, comprising the second plurality of chiplets, wherein the second plurality of PLL circuitries are not disposed on the second plurality of chiplets.

EXAMPLE EMBODIMENT 20. The multi-die package of example embodiment 16, comprising the second plurality of chiplets, wherein the second plurality of PLL circuitries are disposed on the second plurality of chiplets.

What is claimed is:

1. A device comprising:
system phase lock loop (PLL) circuitry to:
receive a primary reference clock,
generate one or more reference clocks from the primary reference clock, and
transmit the one or more reference clocks; and
a plurality of PLL circuitries to:
receive respective reference clocks of the one or more reference clocks,
generate respective sub-reference clocks from the received respective reference clocks, and
transmit the respective sub-reference clocks from respective PLL circuitries of the plurality of PLL circuitries to drive operations of a plurality of chiplets using the respective sub-reference clocks, wherein one or more of the respective sub-reference clocks drive one or more chiplets of the plurality of chiplets.

2. The device of claim 1 comprising the plurality of chiplets, wherein each chiplet of the plurality of chiplets comprises a PLL circuitry of the plurality of PLL circuitries.

3. The device of claim 2, wherein one of the plurality of chiplets comprises the system PLL circuitry.

4. The device of claim 2, comprising a system PLL chiplet that comprises the system PLL circuitry.

5. The device of claim 1 comprising the plurality of chiplets, wherein a chiplet of the plurality of chiplets comprises a corresponding PLL circuitry of the plurality of PLL circuitries and drives at least two chiplets of the plurality of chiplets.

6. The device of claim 5, wherein the at least two chiplets are similar chiplets.

7. The device of claim 6, wherein the at least two chiplets have a same function type.

8. The device of claim 1, wherein the system PLL circuitry is to disable transmission of at least one of at least one of the one or more reference clocks to place a corresponding at least one of the chiplets in an idle mode.

9. A multi-die package comprising:
first system phase lock loop (PLL) circuitry to:
receive a primary reference clock,
generate a first one or more reference clocks from the primary reference clock, and
transmit the first one or more reference clocks;
second system PLL circuitry to:
receive the primary reference clock,
generate a second one or more reference clocks from the primary reference clock,
dither the second one or more reference clocks, and
transmit the second one or more reference clocks; and
a plurality of PLL circuitries comprising:
a first group of PLL circuitries of the plurality of PLL circuitries to receive the first one or more reference clocks; and
a second group of PLL circuitries of the plurality of PLL circuitries to receive the second one or more reference clocks.

10. The multi-die package of claim 9, wherein the first group of PLL circuitries generates respective sub-reference clocks from the first one or more reference clocks and transmits the respective sub-reference clocks to drive operations of a plurality of chiplets.

11. The multi-die package of claim 10, wherein the first system PLL circuitry disables transmission of at least one of the first one or more reference clocks to place a at least one of the chiplets in an idle mode.

12. The multi-die package of claim 9, wherein the second group of PLL circuitries generates respective sub-reference clocks from the first one or more reference clocks and transmits the respective sub-reference clocks to drive operations of a plurality of chiplets.

13. The multi-die package of claim 9, comprising a plurality of dedicated PLL chiplets that comprises the plurality of PLL circuitries.

14. The multi-die package of claim 9, comprising a plurality of chiplets driven using the first and second one or more reference clocks, wherein the plurality of chiplets comprises the plurality of PLL circuitries.

15. The multi-die package of claim 9, comprising:
a plurality of chiplets driven using the first and second one or more reference clocks, and
an interconnect that connects at least two of the plurality of chiplets, wherein at least one of the plurality of PLL circuitries is located on the interconnect.

16. A multi-die package comprising:
first system phase lock loop (PLL) circuitry to:
receive a primary reference clock,
generate first reference clocks from the primary reference clock, and
transmit the first reference clocks; and
a first plurality of PLL circuitries to:
receive the first reference clocks,
generate first sub-reference clocks from the first reference clocks, and
transmit the first sub-reference clocks from the first plurality of PLL circuitries to drive operation of a first plurality of chiplets;
second system phase lock loop (PLL) circuitry to:
receive the primary reference clock,
generate a second reference clocks from the primary reference clock, and
transmit the second reference clocks; and
a second plurality of PLL circuitries to:
receive the second reference clocks,
generate second sub-reference clocks from the second reference clocks, and
transmit the second sub-reference clocks from the second plurality of PLL circuitries to drive operation of a second plurality of chiplets.

17. The multi-die package of claim 16, comprising the first plurality of chiplets, wherein the first plurality of PLL circuitries are not disposed on the first plurality of chiplets.

18. The multi-die package of claim 16, comprising the first plurality of chiplets, wherein the first plurality of PLL circuitries are disposed on the first plurality of chiplets.

19. The multi-die package of claim 16, comprising the second plurality of chiplets, wherein the second plurality of PLL circuitries are not disposed on the second plurality of chiplets.

20. The multi-die package of claim 16, comprising the second plurality of chiplets, wherein the second plurality of PLL circuitries are disposed on the second plurality of chiplets.
